(19) United States
(12) Patent Application Publication
(10) Pub. No.: US 2026/0229267 A1
(43) Pub. Date: Aug. 6, 2026

(54) NONVOLATILE MEMORY DEVICE AND OPERATION METHOD THEREOF

(71) Applicant: SAMSUNG ELECTRONICS CO., LTD., Suwon-si (KR)

(72) Inventors: Taeyoung IM, Suwon-si (KR); Seunghyun KIM, Suwon-si (KR); Kwang-Soo KIM, Suwon-si (KR); Suhwan LIM, Suwon-si (KR)

(73) Assignee: SAMSUNG ELECTRONICS CO., LTD., Suwon-si (KR)

(21) Appl. No.: 19/436,459

(22) Filed: Dec. 30, 2025

(30) Foreign Application Priority Data
Jan. 31, 2025 (KR) 10-2025-0012712

(51) Int. Cl. G11C 11/22

(52) U.S. Cl. CPC G11C 11/2275; G11C 11/2257; G11C 11/2259; G11C 11/2297

(57) ABSTRACT

A nonvolatile memory device may include a string including a ground select transistor, a string select transistor, and memory transistors, and a row decoder configured to control a ground select line connected to the ground select transistor, a string select line connected to the string select transistor, and wordlines respectively connected to the memory transistors. During a first time period when the row decoder provides a program voltage to a target wordline, the row decoder is configured to provide a first voltage to a first wordline between the target wordline and the string select line and a second wordline between the target wordline and the ground select line; and provide a second voltage higher than the first voltage to one of: a first plurality of wordlines between the first wordline and the string select line and a second plurality of wordlines between the second wordline and the ground select line.

### CROSS-REFERENCE TO RELATED APPLICATION

This application claims priority to and the benefit of Korean Patent Application No. 10-2025-0012712 filed with the Korean Patent Office on January 31, 2025, the entire contents of which are incorporated herein by reference.

### BACKGROUND

### a Field

The present disclosure relates to a semiconductor storage device. More specifically, the present disclosure relates to a nonvolatile memory device storing data based on ferroelectrics and an operation method thereof.

### b Description of the Related Art

Ferroelectrics have property of maintaining electric polarization generated based on an electric field even after the electric field is removed. Recently, various studies have been conducted on nonvolatile memory devices that store data based on threshold voltage that changes according to the electric polarization of a ferroelectric layer included in a memory transistor.

The electric polarization of the ferroelectric layer may vary depending on strength of the effective electric field applied to the ferroelectric layer. The strength of the effective electric field applied to the ferroelectric layer may vary depending on amount of induced charge on channel of the memory transistor. These characteristics of ferroelectric-based memory transistor make it difficult to finely tune the threshold voltage of the memory transistor based on gate voltage control of the memory transistor.

Meanwhile, when the channel of the ferroelectric-based memory transistor is floated and thereafter a program voltage is provided to a target wordline connected to the gate terminal of the memory transistor, the threshold voltage of the memory transistor may be adjusted more finely. However, when a program voltage is supplied to the target wordline while the channel of the memory transistor is floated, the threshold voltage of the memory transistor may not be sufficiently changed because the channel voltage of the memory transistor is unintentionally boosted, and the threshold voltage of other memory transistors sharing the target wordline may be unintentionally changed by the program voltage.

### SUMMARY

The present disclosure is intended to solve the technical problems described above. More specifically, an object of the present disclosure is to provide a nonvolatile memory device storing data based on a threshold voltage of a memory transistor including a ferroelectric layer, and operation method thereof.

According to an embodiment of present disclosure, a nonvolatile memory device may include: a string including a ground select transistor, a string select transistor, and a plurality of memory transistors; and a row decoder configured to control a ground select line connected to the ground select transistor, a string select line connected to the string select transistor, and a plurality of wordlines respectively connected to the plurality of memory transistors. During a first time period in which the row decoder provides a program voltage to a target wordline, which is one of the plurality of wordlines, the row decoder is configured to: provide a first voltage to a first focus criteria wordline, among the plurality of wordlines, located between the target wordline and the string select line, and to a second focus criteria wordline, among the plurality of wordlines, located between the target wordline and the ground select line; and provide a second voltage higher than the first voltage to at least one of: a first plurality of criteria outside wordlines, among the plurality of wordlines, located between the first focus criteria wordline and the string select line; and a second plurality of criteria outside wordlines, among the plurality of wordlines, located between the second focus criteria wordline and the ground select line.

According to an embodiment of present disclosure, an operation method of a nonvolatile memory device including a program string and an inhibit string sharing a string select line, a ground select line, and a plurality of wordlines, may include: setting a voltage level of the plurality of wordlines to a first voltage; decreasing a voltage level of first and second focus criteria wordlines among the plurality of wordlines to a second voltage; and increasing a voltage level of a target wordline, which is one of the plurality of wordlines and is located between the first and second focus criteria wordlines, to a third voltage. During performing the decreasing and increasing, among the plurality of wordlines, voltage levels of a first plurality of criteria outside wordlines located between the first focus criteria wordline and the string select line, and voltage levels of a second plurality of criteria outside wordlines located between the second focus criteria wordline and the ground select line, are maintained with the first voltage.

According to an embodiment of present disclosure, a nonvolatile memory device may include: a program string including first and second focus criteria memory transistors, and a program memory transistor connected between the first and second focus criteria memory transistors; an inhibit string including third and fourth focus criteria memory transistors, and an inhibit memory transistor connected between the third and fourth focus criteria memory transistors; and a row decoder configured to control a first focus criteria wordline connected to the first and third focus criteria memory transistors, a second focus criteria wordline connected to the second and fourth focus criteria memory transistors, and a target wordline connected to the program memory transistor and the inhibit memory transistor. During a first time period in which the row decoder provides a program voltage to the target wordline: the row decoder is configured to provide a ground voltage to the first focus criteria wordline and the second focus criteria wordline, and a first channel potential level corresponding to the program memory transistor is lower than a second channel potential level corresponding to the inhibit memory transistor.

### BRIEF DESCRIPTION OF THE DRAWINGS

FIG. 1 is a block diagram showing a storage device according to an embodiment of the present disclosure.

FIG. 2 is a block diagram showing the nonvolatile memory device of FIG. 1 in more detail.

FIG. 3 is a drawing showing configuration of a part of the memory cell array of FIG. 2 in more detail.

FIG. 4 is a diagram showing the configuration of the memory transistor of FIG. 3.

FIG. 5 is a diagram showing a method for controlling the plurality of wordlines according to the charge control program logic of FIG. 2.

FIG. 6 is a timing diagram showing in more detail the operation of a nonvolatile memory device according to the charge control program logic of FIG. 2.

FIGS. 7 to 12 are diagrams showing channel potentials of program strings and inhibit strings between the first to fourth time points of FIG. 6.

FIG. 13 is a diagram showing the operation of the nonvolatile storage device of FIG. 1 according to an embodiment of the present disclosure.

FIG. 14 is a diagram showing the relationship between the program voltage and the threshold voltage of the program memory transistor according to the embodiment of FIG. 13.

FIG. 15 is a timing diagram showing in more detail the operation of a nonvolatile memory device according to the charge control program logic of FIG. 2 according to an embodiment.

FIG. 16 is a diagram showing the channel potential of a program string between a third time point and a fourth time point according to the embodiment of FIG. 15.

FIG. 17 is a timing diagram showing in more detail the operation of a nonvolatile memory device according to the charge control program logic of FIG. 2 according to an embodiment.

FIG. 18 is a diagram showing the voltage difference between a target wordline and adjacent wordlines according to the embodiment of FIG. 17.

FIG. 19 is a timing diagram showing in more detail the operation of a nonvolatile memory device according to the charge control program logic of FIG. 2 according to an embodiment.

### DETAILED DESCRIPTION OF THE EMBODIMENTS

Hereinafter, various embodiments will be described in detail and clearly to such an extent that an ordinary one in the art easily implements the present disclosure. Specific details such as detailed components and structures are merely provided to assist the overall understanding of the various embodiments. Therefore, it should be apparent to those skilled in the art that various changes and modifications of the embodiments described herein may be made without departing from the scope and spirit of the present disclosure. Moreover, descriptions of well-known functions and structures are omitted for clarity and brevity. In the following drawings or in the detailed description, configurations may be connected with any other components except for components illustrated in a drawing or described in the detailed description. The terms described below are terms defined in consideration of the functions of the present disclosure and are not limited to a specific function. The definitions of the terms should be determined based on the contents throughout the specification.

Components that are described in the detailed description with reference to the terms “driver”, “block”, etc. will be implemented with software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, a microelectromechanical system (MEMS), a passive element, or a combination thereof.

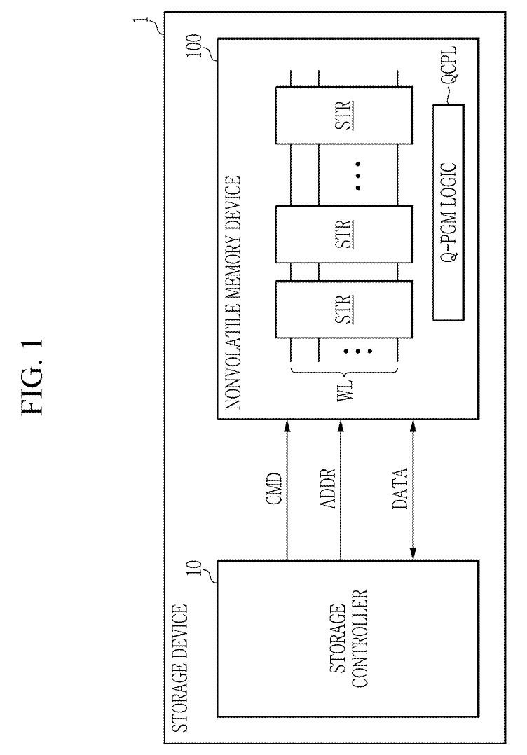

FIG. 1 is a block diagram showing a storage device according to an embodiment of the present disclosure. Referring to FIG. 1, a storage device 1 may include a storage controller 10 and a nonvolatile memory device 100.

The storage controller 10 may store data DATA in the nonvolatile memory device 100 or read data DATA stored in the nonvolatile memory device 100. For example, the storage controller 10 may store data DATA in the nonvolatile memory device 100 or read data DATA stored in the nonvolatile memory device 100, by issuing or providing command CMD and address ADDR to the nonvolatile memory device 100.

The nonvolatile memory device 100 may include a plurality of strings STRs that share a plurality of wordlines WLs. Each of the plurality of strings STR may include a plurality of memory cells connected in series, and each of the plurality of memory cells may be implemented as a memory transistor. The plurality of memory transistors may store data DATA provided from the storage controller 10. For example, the nonvolatile memory device 100 may program data DATA to the plurality of strings STR (more specifically, to a plurality of memory transistors) or provide data DATA stored in a plurality of strings STR to the storage controller 10, based on the command CMD and address ADDR provided from the storage controller 10.

The nonvolatile memory device 100 may determine whether to program data for each string STR. For example, the nonvolatile memory device 100 may program data to a specific string STR and not program data to other strings STR. In other words, the nonvolatile memory device 100 may store new data by programming a specific string STR, and inhibit (or program inhibit) other strings STR to prevent the stored data from being unintentionally damaged. Hereinafter, the string to be programmed STR is referred to as program string STR_PGM, and the string to be inhibited STR is referred to as inhibit string STR_IHB.

Each of the memory transistors included in the plurality of strings STR may store data based on electric polarization of ferroelectric. For example, each memory transistor may include a ferroelectric layer. The threshold voltage of each memory transistor may vary depending on the electric polarization of the ferroelectric layer. Each memory transistor may store data in a form of threshold voltage.

The electric polarization of the ferroelectric layer included in each memory transistor may be determined based on a voltage level of corresponding wordline WL, and amount of induced charge generated on a channel of the memory transistor based on the voltage level of the wordline WL. For example, the electric polarization of the ferroelectric layer may vary depending on a strength of an effective electric field applied to the ferroelectric layer, and the strength of an effective electric field applied to the ferroelectric layer may vary depending on the amount of induced charge induced in the channel of the memory transistor. These characteristics of ferroelectric-based memory transistors may make it difficult to precisely adjust the threshold voltage of the memory transistor (e.g., adjust linearly to the voltage level of the wordline WL) by adjusting the voltage level of the wordline WL connected to a gate terminal of the memory transistor. In other words, due to the characteristics of ferroelectric-based memory transistors, it may be difficult to accurately store data in ferroelectric-based memory transistors.

The amount of induced charge in a channel of a ferroelectric-based memory transistor may be controlled by floating the channel of the memory transistor. For example, when a certain voltage level (e.g., a pass voltage) is applied to a wordline WL connected to a specific memory transistor while the channel of the memory transistor is not floated, a specific amount of induced charge may be generated on the channel of the memory transistor. Thereafter, when the channel of the memory transistor is floated, the amount of induced charge which affects the intensity of the effective electric field applied to the memory transistor may be controlled to a specific level. Thereafter, when a program voltage (e.g., a voltage high enough to change the electric polarization) is applied to the wordline WL connected to the gate terminal of the memory transistor, the threshold voltage of the memory transistor may be finely adjusted.

However, if a program voltage is supplied to a wordline WL connected to a specific memory transistor while the channel of the memory transistor is floated, the channel voltage of the memory transistor may be unintentionally boosted. For example, if the channel of the memory transistor is floated, the channel potential level of the memory transistor may be boosted to a level similar to the program voltage. In this case, the difference between the voltage level of the wordline WL and the channel potential level of the corresponding memory transistor may become unintentionally small, so that the program operation for the corresponding memory transistor may fail (for example, the threshold voltage may not be sufficiently changed).

Additionally, while programming a memory transistor included in a specific string STR (e.g., a program string STR_PGM), a memory transistor included in another string STR (e.g., an inhibit string STR_IHB) that shares a wordline WL with the string STR may be unintentionally programmed. For example, when a program voltage is applied to a specific wordline WL, the threshold voltage of the memory transistors connected to the wordline WL among the memory transistors included in the inhibit string STR_IHB may change unintentionally. For a more specific example, if the difference between the channel potential and the program voltage of the memory transistor is too large, the threshold voltage of the memory transistor may change unintentionally.

The nonvolatile memory device 100 according to an embodiment of the present disclosure may perform a program operation based on charge control program logic QCPL. For example, the nonvolatile memory device 100 may minimize an unintended channel potential boost occurring on a program string STR_PGM and maximize a channel potential boost for an inhibit string STR_IHB, based on charge control program logic QCPL. In this case, data may be programmed correctly as intended in the program string STR_PGM, and the phenomenon of data being unintentionally programmed in the inhibit string STR_IHB may be prevented. Therefore, according to an embodiment of the present disclosure, the reliability of data stored in the nonvolatile memory device 100 may be improved. The operation scheme of the nonvolatile memory device 100 based on charge control program logic QCPL will be described in more detail below.

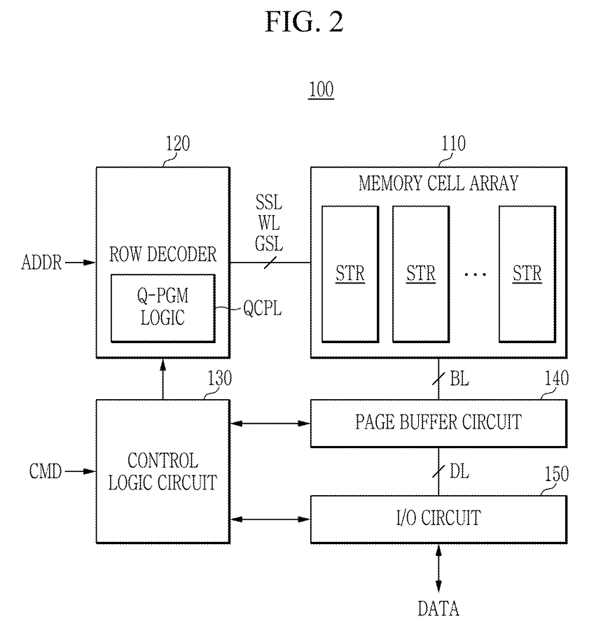

FIG. 2 is a block diagram showing the nonvolatile memory device of FIG. 1 in more detail. Referring to FIGS. 1 and 2, the nonvolatile memory device 100 may include a memory cell array 110, a row decoder 120, a control logic circuit 130, a page buffer circuit 140, and an input/output circuit 150.

For a more concise explanation hereinafter, FIG. 2 illustrates that various signals, such as a command CMD, an address ADDR, and data DATA, are directly provided to various functional blocks (e.g., a row decoder 120, a control logic circuit 130, and an input/output circuit 150). However, the scope of the present disclosure is not limited to the specific manner in which commands CMD, addresses ADDR, and data DATA are transmitted between the storage controller 10 and the nonvolatile memory device 100.

The memory cell array 110 may include a plurality of strings STR. A plurality of strings STR may contain the plurality of memory cells. The plurality of strings STR may be connected to different bitline BL each other. The plurality of strings STR may share a string select line SSL, the plurality of wordlines WL, and a ground select line GSL.

The row decoder 120 may be connected to a memory cell array 110 via a string select line SSL, the plurality of wordlines WL, and a ground select line GSL. The row decoder 120 may receive an address ADDR from the storage controller 10. The row decoder 120 may decode the address ADDR, and may control the voltage levels of the string select line SSL, the plurality of wordlines WL, and the ground select line GSL based on the decoded result.

The row decoder 120 may operate based on charge control program logic QCPL. For example, the row decoder 120 may minimize the channel potential boost for the memory transistor of the program string STR_PGM and maximize the channel potential boost for the memory transistor of the inhibit string STR_IHB by controlling the string select line SSL, the plurality of wordlines WL, and the ground select line GSL based on the charge control program logic QCPL.

The control logic circuit 130 may receive the command CMD from the storage controller 10. The control logic circuit 130 may control overall operations of the nonvolatile memory device 100 based on the command CMD. For example, the control logic circuit 130 may control the operation of the row decoder 120, the page buffer circuit 140, and the input/output circuit 150 based on the command CMD.

The page buffer circuit 140 may temporarily store user data DATA read from the memory cell array 110 through the plurality of bitlines BL or temporarily store data DATA to be stored in the memory cell array 110.

The page buffer circuit 140 may be connected to the memory cell array 110 through the plurality of bitlines BL. The page buffer circuit 140 may control the voltage levels of a plurality of bitlines BL based on a control of the control logic circuit 130. For example, the page buffer circuit 140 may change the voltage level of each of the plurality of bitlines BL to a ground voltage or a power supply voltage.

The input/output circuit 150 may be connected to the page buffer circuit 140 through a plurality of data lines DL. The input/output circuit 150 may output data DATA stored in the page buffer circuit 140 to the storage controller 10, or provide data DATA provided from the storage controller 10 to the page buffer circuit 140.

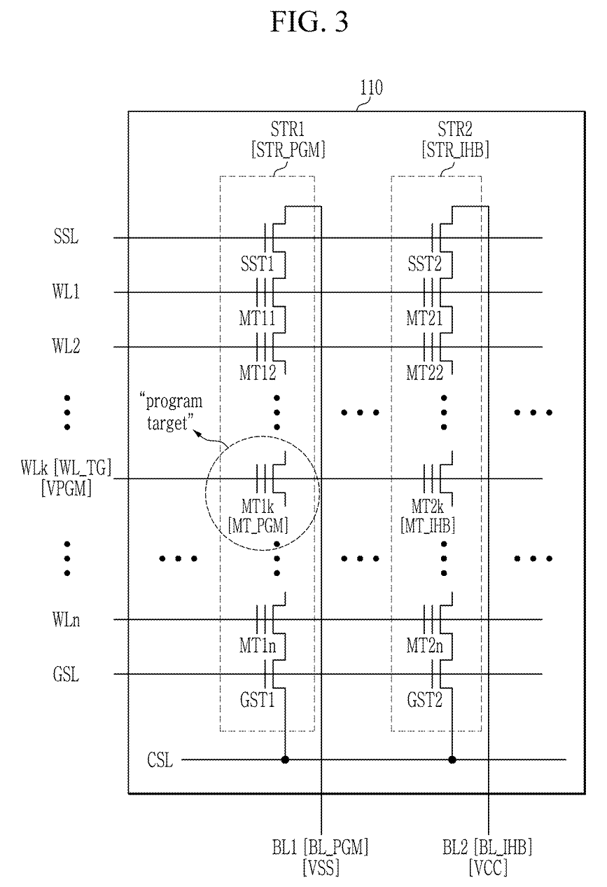

FIG. 3 is a drawing showing configuration of a part of the memory cell array of FIG. 2 in more detail. Referring to FIGS. 1 to 3, the memory cell array 110 may include a first string STR1 and a second string STR2. In the following, for a more concise explanation, the configuration and function of the first string STR1 and the second string STR2 among the plurality of strings STR included in the memory cell array 110 will be representatively described. However, the scope of the present disclosure is not limited thereto.

The first string STR1 may be connected to a first bitline BL1, and the second string STR2 may be connected to a second bitline BL2.

Each of the first string STR1 and the second string STR2 may include a string select transistor SST, a plurality of memory transistors MT, and a ground select transistor GST. For example, the first string STR1 may include a first string select transistor SST1, memory transistors MT11 to MT1n, and a first ground select transistor GST1. The second string STR2 may include a second string select transistor SST2, memory transistors MT21 to MT2n, and a second ground select transistor GST2.

The first string STR1 and the second string STR2 may be connected to a string select line SSL, first to n-th wordlines WL1 to WLn, and a ground select line GSL. For example, a string select line SSL may be connected to gate terminals of the first and second string select transistors SST1, SST2; the first to n-th wordlines WL1 to WLn may be connected to gate terminals of the memory transistors MT11 to MT1n and the memory transistors MT21 to MT2n, respectively; and a ground select line GSL may be connected to gate terminals of the first and second ground select transistors GST1, GST2.

The first string select transistor SST1, memory transistors MT11 to MT1n, and the first ground select transistor GST1 may be connected in series. For example, the first string select transistor SST1, the memory transistors MT11 to MT1n, and the first ground select transistor GST1 may be connected in series between the first bitline BL1 and the common source line CSL. The second string select transistor SST2, memory transistors MT21 to MT2n, and the second ground select transistor GST2 may be connected in series. For example, the second string select transistor SST2, the memory transistors MT21 to MT2n, and the second ground select transistor GST2 may be connected in series between the second bitline BL2 and the common source line CSL. In an embodiment, the common source line CSL may be connected to ground voltage.

Each of the plurality of memory transistors MT may correspond to one memory cell. For example, each of the plurality of memory transistors MT may store data based on its threshold voltage.

Each of the first and second string select transistors SST1, SST2 may determine whether to connect a plurality of memory transistors MT to the bitline BL. For example, the first string select transistor SST1 may determine whether to connect the memory transistors MT11 to MT1n to the first bitline BL1 based on the voltage level of the string select line SSL.

Each of the first and second ground select transistors GST1, GST2 may determine whether to connect the plurality of memory transistors MT to the common source line CSL. For example, the first ground select transistor GST1 may determine whether to connect the memory transistors MT11 to MT1n to the common source line CSL based on the voltage level of the ground select line GSL.

The nonvolatile memory device 100 may perform a program operation for the first string STR1 based on the command CMD and the address ADDR. Hereinafter, for a more concise explanation, an embodiment in which the nonvolatile memory device 100 programs a memory transistor MT1k (hereinafter, it may be referred to as a program memory transistor MT_PGM or a program target memory transistor) included in the first string STR1 will be representatively described.

The page buffer circuit 140 may provide a ground voltage VSS to the first bitline BL1. The row decoder 120 may provide a program voltage VPGM to a wordline connected to a program memory transistor MT_PGM (e.g., the k-th wordline WLk; hereinafter, it may be referred to as a target wordline WL_TG).

In an embodiment, the program voltage VPGM may be a voltage high enough to change the threshold voltage of the program memory transistor MT_PGM. For example, the program voltage VPGM may be a voltage that generates an effective electric field strong enough (e.g., stronger than the coercive electric field) to change the electric polarization of the ferroelectric layer. That is, the program voltage VPGM may be a voltage sufficiently higher than a coercive voltage, which represents the potential difference across the ferroelectric layer required to generate a coercive electric field (more specifically, a voltage higher than the sum of the channel potential and coercive voltage of the program memory transistor MT_PGM which described below).

In an embodiment, the first string STR1 may also be referred to as a program string STR_PGM. The first bitline BL1 may also be referred to as a program bitline BL_PGM.

While performing a program operation for the program memory transistor MT_PGM, the nonvolatile memory device 100 may perform an inhibit operation for the second string STR2. For example, the nonvolatile memory device 100 may protect, among the memory transistors MT21 to MT2n included in the second string STR2, a memory transistor MT2k (hereinafter, referred to as an inhibit memory transistor MT_IHB or an inhibit target memory transistor) connected to the k-th wordline WLk from being programmed. For example, the page buffer circuit 140 may provide a power supply voltage VCC to the second bitline BL2.

In an embodiment, the second string STR2 may be referred to as an inhibit string STR_IHB. The second bitline BL2 may also be referred to as an inhibit bitline BL_IHB.

That is, according to an embodiment of the present disclosure, different voltages may be provided to the program bitline BL_PGM and the inhibit bitline BL_IHB. The nonvolatile memory device 100 may control a plurality of wordlines WL based on a charge control program logic QCPL, so that a channel potential level of the inhibit memory transistor MT_IHB is higher than a channel potential level of the program memory transistor MT_PGM while a program voltage VPGM is provided to a target wordline WL_TG. In this case, even if the program voltage VPGM is supplied to the target wordline WL_TG, only the threshold voltage of the program memory transistor MT_PGM may change, and the threshold voltage of the inhibit memory transistor MT_IHB may not change. A control scheme of the plurality of wordlines WLs based on charge control program logic QCPL and a detailed principle of changing channel potential levels of the inhibit memory transistor MT_IHB and the program memory transistor MT_PGM while the program voltage VPGM is provided to the target wordline WL_TG will be described in more detail with reference to the drawings below.

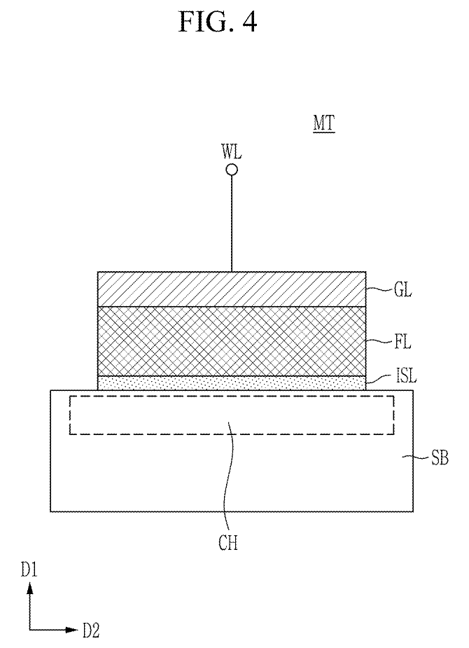

FIG. 4 is a diagram showing the configuration of the memory transistor of FIG. 3. Referring to FIGS. 1 to 4, the plurality of memory transistors MT included in one string STR may share a silicon body SB. For example, memory transistors MT11 to MT1n may be formed on a single silicon body SB. The silicon body SB may be made of intrinsic silicon, doped silicon, or a combination thereof. However, the scope of the present disclosure is not limited to the specific chemical composition of the silicone body SB. For a more concise explanation, hereinafter, the configuration of one of the plurality of memory transistors MT included in the memory cell array 110 is representatively described.

The memory transistor MT may include a gate layer GL, a ferroelectric layer FL, and an isolation layer ISL. The gate layer GL, the ferroelectric layer FL, and the isolation layer ISL may be formed on the silicon body SB along a first direction D1.

The gate layer GL may form a gate terminal of the memory transistor MT. For example, the gate layer GL may include a conductive material such as a metal, a metal compound, or polysilicon.

The ferroelectric layer FL may form electric polarization depending on the strength of the effective electric field. For example, the ferroelectric layer FL may include ferroelectric material such as Lead Zirconate Titanate (PZT), Strontium Bismuth Tantalate (SBT), etc. However, the scope of the present disclosure is not limited to the specific chemical composition of the ferroelectric layer FL. For example, the ferroelectric layer FL may include various types of ferroelectric materials such as BaTiO₃, LiNbO₃, HfO₂, KNbO₃, etc.

The isolation layer ISL may isolate between the ferroelectric layer FL and the silicon body SB. For example, the isolator ISL may include various types of insulator materials, such as silicon oxide. However, the scope of the present disclosure is not limited to the specific chemical composition of the isolation layer ISL.

In an embodiment, the memory transistor MT may not include an isolation layer ISL. In this case, the ferroelectric layer FL and the silicon body SB may contact directly. However, the scope of the present disclosure is not limited thereto.

A channel CH may be formed in the silicon body SB. For example, depending on the voltage level of the wordline WL, charge may move in the second direction D2, which is the direction in which the plurality of memory transistors MT are connected in series. In an embodiment, the first direction D1 may be perpendicular to the second direction D2.

The threshold voltage of the memory transistor MT may vary depending on the electric polarization of the ferroelectric layer FL. Therefore, whether charges are able to move in the second direction D2 on the silicon body SB may be determined based on the amount of electric polarization of the ferroelectric layer FL (or, the threshold voltage of the memory transistor MT) and the voltage level of the wordline WL.

The amount of electric polarization of the ferroelectric layer FL may be determined based on the difference between the voltage level of the wordline WL and the potential level of the channel CH. For example, the strength of the effective electric field applied to the ferroelectric layer FL may be determined based on the difference between the voltage level of the wordline WL and the potential level of the channel CH.

The potential level of a channel CH may vary according to the amount of charge induced in the channel CH in response to the voltage of the wordline WL. That is, the potential level of the channel CH may vary depending on the amount of induced charge concentrated (or focused) on the channel CH through the second direction D2. Therefore, the electric polarization of the ferroelectric layer FL may vary depending on the amount of charge induced in the channel CH in response to the voltage of the wordline WL.

In an embodiment, whether a conductive path is formed between a bitline BL and a common source line CSL through the channel CH of each of the plurality of memory transistors MT may be determined based on a voltage level of each of a plurality of wordlines WL and a threshold voltage of each of a plurality of memory transistors MT.

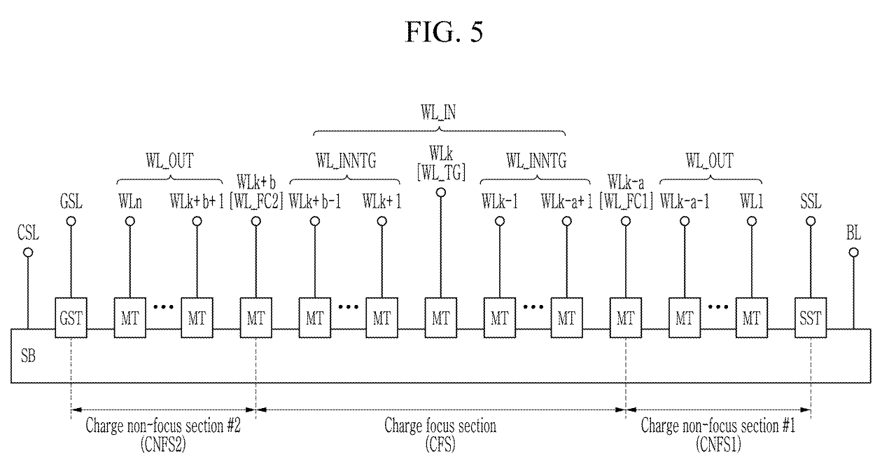

FIG. 5 is a diagram showing a method for controlling the plurality of wordlines according to the charge control program logic of FIG. 2. Referring to FIGS. 1 to 5, one string STR (e.g., a program string STR_PGM or an inhibit string STR_IHB) may include a string select transistor SST, a plurality of memory transistors MT, and a ground select transistor GST formed on a silicon body SB. The row decoder 120 may control the string select line SSL, the first to n-th wordlines WL1 to WLn, and the ground select line GSL based on the charge control program logic QCPL.

Hereinafter, for a more concise explanation, an example in which the nonvolatile memory device 100 determines the k-th wordline WLk as the target wordline WL_TG is representatively described. That is, hereinafter, an embodiment will be described in which a row decoder 120 programs a program memory transistor MT_PGM connected to the k-th wordline WLk and performs a program inhibit operation on an inhibit memory transistor MT_IHB connected to the k-th wordline WLk. However, the scope of the present disclosure is not limited thereto. For example, the nonvolatile memory device 100 may determine any wordline among the first to n-th wordlines WL1 to WLn as the target wordline WL_TG.

The row decoder 120 may determine one of wordlines located between the target wordline WL_TG and the string select line SSL, and one of wordlines located between the target wordline WL_TG and the ground select line GSL as a focus criteria wordline WL_FC. For example, the row decoder 120 may determine the (k-a)-th wordline WLk-a as a first focus criteria wordline WL_FC1 and may determine the (k+b)-th wordline WLk+b as a second focus criteria wordline WL_FC2.

In an embodiment, an interval between the target wordline WL_TG and the first focus criteria wordline WL_FC1 may be equal to the spacing between the target wordline WL_TG and the second focus criteria wordline WL_FC2. For example, a number of wordlines located between the target wordline WL_TG and the first focus criteria wordline WL_FC1 may be equal to a number of wordlines located between the target wordline WL_TG and the second focus criteria wordline WL_FC2. In other words, 'a' and 'b' may be natural numbers greater than or equal to '1'. However, the scope of the present disclosure is not limited thereto.

In an embodiment, the memory transistors MT connected to the focus criteria wordlines WL_FC may be referred to as 'focus criteria memory transistors'.

Before providing the program voltage VPGM to the target wordline WL_TG, the row decoder 120 may set the voltage levels of the string select line SSL, the first to n-th wordlines WL1 to WLn, and the ground select line GSL as a pass voltage (hereinafter, it will be referred to as “VPS”). In this case, induced charge may be generated in the channel of the program memory transistor MT_PGM connected to the target wordline WLk.

In an embodiment, the pass voltage VPS may be a voltage that is higher than the threshold voltage of each memory transistor MT, but not high enough to change the electric polarization of the ferroelectric layer FL. In other words, the pass voltage VPS may be a voltage high enough to turn on each memory transistor MT, but not high enough to change the threshold voltage.

In an embodiment, a string select transistor SST (e.g., a first string select transistor SST1) and a ground select transistor GST (e.g., a first ground select transistor GST1) included in a program string STR_PGM may be turned on in response to the pass voltage VPS. On the other hand, in response to the pass voltage VPS, the string select transistor SST (e.g., the second string select transistor SST2) and the ground select transistor GST (e.g., the second ground select transistor GST2) included in the inhibit string STR_IHB may not be turned on.

Thereafter, the row decoder 120 may turn off a memory transistor MT connected to the first focus criteria wordline WL_FC1 and a memory transistor MT connected to the second focus criteria wordline WL_FC2. For example, the row decoder 120 may provide a turn-off voltage to the first focus criteria wordline WL_FC1 and the second focus criteria wordline WL_FC2. In this case, a certain amount of induced charge may be trapped in a charge focus section CFS on a silicon body SB (e.g., a section between a memory transistor MT connected to the first focus criteria wordline WL_FC1 and a memory transistor MT connected to the second focus criteria wordline WL_FC2).

In an embodiment, the turn-off voltage may be a ground voltage VSS. However, the scope of the present disclosure is not limited thereto, and the turn-off voltage may be any voltage level lower than the threshold voltage of the memory transistor MT connected to the first focus criteria wordline WL_FC1 and the memory transistor MT connected to the second focus criteria wordline WL_FC2. However, for the sake of simplicity, in the following description, it will be assumed that the turn-off voltage is ground voltage VSS.

Thereafter, the row decoder 120 may provide a program voltage VPGM to the target wordline WL_TG. In this case, since the channel CH of the program memory transistor MT_PGM floats while the program voltage VPGM is supplied to the target wordline WL_TG, the amount of charge induced in the channel of the program memory transistor MT_PGM may be limited to less than a total amount of charge trapped in the charge focus section CFS. That is, according to an embodiment of the present disclosure, the amount of induced charge affects to the program operation of the program memory transistor MT_PGM may be controlled based on the charge control program logic QCPL. Therefore, according to the embodiment of the present disclosure, the voltage level of the program memory transistor MT_PGM may be controlled more accurately.

In an embodiment, the channel potential of the charge focus section CFS may vary depending on the length of the charge focus section CFS. For example, the channel potential in the charge focus section CFS may vary depending on the 'a' and 'b'.

The memory transistors MT formed on the charge focus section CFS of each string STR may be referred to as 'criteria internal memory transistors'. The wordlines each connected to the criteria internal memory transistors may be referred to as criteria internal wordlines WL_IN. For example, the (k-a+1)-th to (k+b-1)-th wordlines WLk-a+1 to WLk+b-1 may be referred to as criteria internal wordlines WL_IN.

Among the criteria internal wordlines WL_IN, wordlines other than the target wordline WL_TG may be referred to as criteria internal non-target wordlines WL_INNTG. For example, the (k-a+1)-th to (k-1)-th wordlines WLk-a+1 to WLk-1, and the (k+1)-th to (k+b-1)-th wordlines (WLk-a+1 to WLk+b-1) may be referred to as criteria internal non-target wordlines WL_INNTG.

The regions on the silicon body SB corresponding to each string STR excluding the charge focus section CFS may be referred to as the charge non-focus section CNFS. For example, a section between a memory transistor MT connected to a first focus criteria wordline WL_FC1 and a string select transistor SST may be referred to as a first charge non-focus section CNFS1; and a section between a memory transistor MT connected to a second focus criteria wordline WL_FC2 and a ground select transistor GST may be referred to as a second charge non-focus section CNFS2.

The memory transistors MT formed on the charge non-focus section CNFS of each string STR may be referred to as 'criteria outside memory transistors'. The wordlines respectively connected to the criteria outside memory transistors may be referred to as criteria outside wordlines WL_OUT. For example, the first to (k-a-1)-th wordlines WL1 to WLk-a-1 and the (k+b+1)-th to n-th wordlines WLk+b+1 to WLn may be referred to as criteria outside wordlines WL_OUT.

The row decoder 120 may provide a voltage higher than the turn-off voltage to one or more of the plurality of criteria outside wordlines WL_OUT while providing a program voltage to the target wordline WL_TG. For example, the row decoder 120 may provide a pass voltage VPS (alternatively, any voltage that is higher than the ground voltage VSS and lower than the pass voltage VPS) to one or more of the plurality of criteria outside wordlines WL_OUT while providing the program voltage to the target wordline WL_TG. However, for a more concise explanation, hereinafter, it is assumed that the row decoder 120 provides the pass voltage VPS to one or more of the plurality of criteria outside wordlines WL_OUT while providing the program voltage to the target wordline WL_TG.

Among a plurality of memory transistors MT included in a program string STR_PGM, the channel potential of memory transistors MT connected to criteria outside wordlines WL_OUT where the pass voltage VPS has been provided may not change significantly. For example, since the string select transistor SST and ground select transistor GST of the program string STR_PGM are turned on, the channel potential of the charge non-focus section CNFS may be determined based on the voltage levels of the common source line CSL and the program bitline BL_PGM.

On the other hand, among a plurality of memory transistors MT included in an inhibit string STR_IHB, the channel potential of memory transistors MT connected to criteria outside wordlines WL_OUT where the pass voltage VPS has been provided may be determined based on the pass voltage VPS. For example, since the string select transistor SST and ground select transistor GST of the inhibit string STR_IHB are turned off, the channel potential of the charge non-focus section CNFS may rise based on the pass voltage VPS. In this case, while the program voltage is supplied to the target wordline WL_TG, the channel potential of the charge focus section CFS included in the inhibit string STR_IHB may also rise due to the channel potential of the charge non-focus section CNFS. In this case, the difference between the channel potential of the inhibit memory transistor MT_IHB and the program voltage VPGM may be minimized.

In an embodiment, the channel potential of the charge focus section CFS included in the inhibit string STR_IHB may rise due to the channel potential of the charge non-focus section CNFS for various reasons. That is, potential sharing may occur between the charge focus section CFS and the charge non-focus section CNFS. For example, even when the focus criteria transistor WL_FC is turned off, leakage current or charge tunneling (e.g., band-to-band tunneling) may occur between the charge non-focus section CNFS and the charge focus section CFS. In this case, the channel potential of the charge focus section CFS may change to a level similar to the channel potential of the charge non-focus section CNFS. However, the scope of the present disclosure is not limited to the specific reason why the channel potentials of the charge non-focus section CNFS and the charge focus section CFS are set with similar levels.

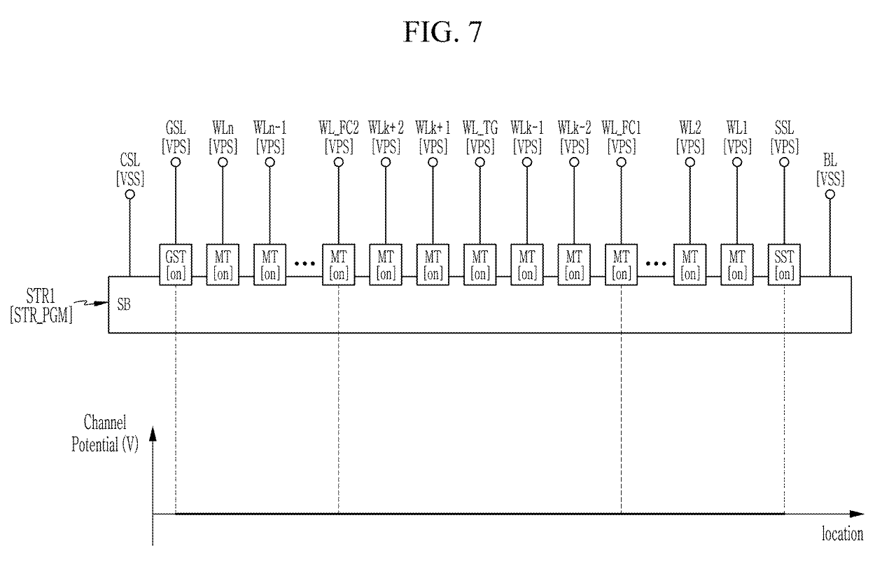

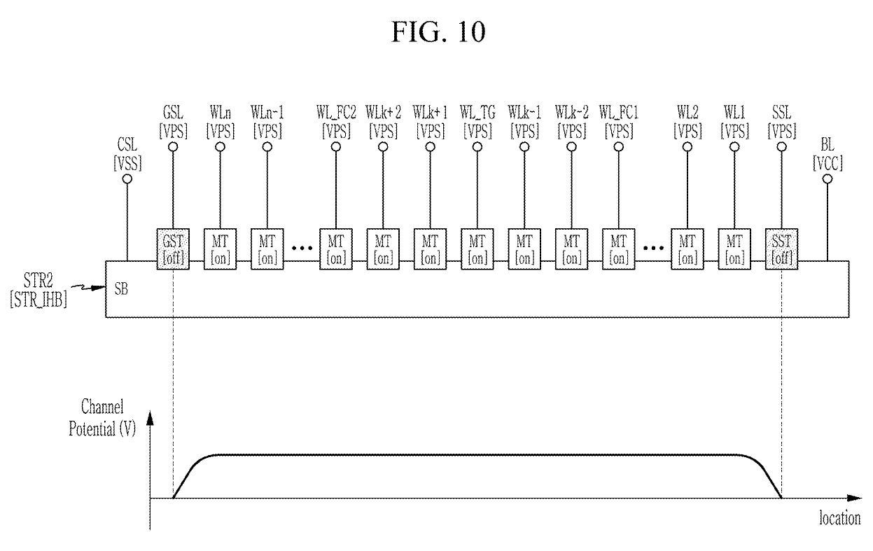

That is, according to an embodiment of the present disclosure, while the program voltage VPGM is provided to the target wordline WL_TG, the channel potentials of the program memory transistor MT_PGM and the inhibit memory transistor MT_IHB may be difference each other. For example, while the program voltage VPGM is provided to the target wordline WL_TG, the channel potential of the program memory transistor MT_PGM may be lower than the channel potential of the inhibit memory transistor MT_IHB. In this case, even if the program voltage VPGM is supplied to the target wordline WL_TG, the program memory transistor MT_PGM may be programmed and the inhibit memory transistor MT_IHB may not be programmed. The channel potential of the controlled program string STR_PGM based on the charge control program logic QCPL is described in more detail with reference to FIGS. 7 to 9 below, and the channel potential of the inhibit string STR_IHB is described in more detail with reference to FIGS. 10 to 12 below.

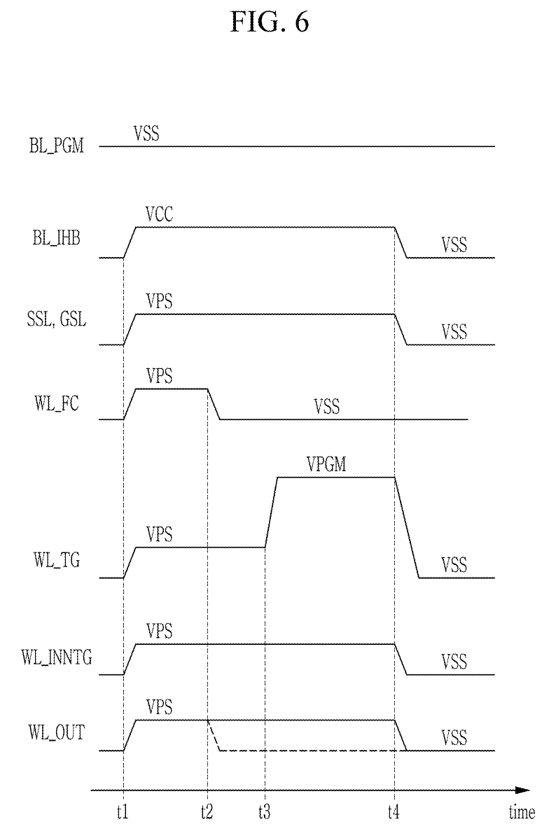

FIG. 6 is a timing diagram showing in more detail the operation of a nonvolatile memory device according to the charge control program logic of FIG. 2. The horizontal axis of FIG. 6 may represent time, and the vertical axis may represent voltage level.

Referring to FIGS. 1 to 6, before a first time point t1, the page buffer circuit 140 may provide a ground voltage VSS to the program bitline BL_PGM and the inhibit bitline BL_IHB. The row decoder 120 may provide a ground voltage VSS to a plurality of wordlines WL, string select lines SSL, and ground select lines GSL.

At the first time point t1, the page buffer circuit 140 may maintain the voltage level of the program bitline BL_PGM at the ground voltage VSS and raise the voltage level of the inhibit bitline BL_IHB to the power supply voltage VCC. The row decoder 120 may increase the voltage levels of a plurality of wordlines WL, string select lines SSL, and ground select lines GSL to a pass voltage VPS.

In an embodiment, the page buffer circuit 140 may raise the voltage level of the inhibit bitline BL_IHB to the power supply voltage VCC at a time point prior to the first time point t1, alternatively. That is, the scope of the present disclosure is not limited to a specific time point when the voltage level of the inhibit bitline BL_IHB rises to the power supply voltage VCC.

At the second time point t2, the row decoder 120 may decrease the voltage level of focus criteria wordlines WL_FC to the ground voltage VSS. For example, the row decoder 120 may turn off the focus criteria memory transistors by reducing the voltage level of the focus criteria wordlines WL_FC.

At the third time point t3, the row decoder 120 may increase the voltage level of the target wordline WL to the program voltage VPGM.

At the fourth time point t4, the row decoder 120 may decrease the voltage level of the target wordline WL to the ground voltage VSS. That is, the program operation for the program memory transistor MT_PGM of the nonvolatile memory device 100 may be terminated at the fourth time point t4. For example, the row decoder 120 may decrease the voltage level of the plurality of wordlines WL, string select line SSL, and ground select line GSL to the ground voltage VSS, and the page buffer circuit 140 may decrease the voltage level of the inhibit bitline BL_IHB to the ground voltage VSS.

The row decoder 120 may maintain the voltage level of the internal non-target wordlines WL_INNTG with the pass voltage VPS between the second time point t2 and the fourth time point t4.

The row decoder 120 may maintain the voltage level of the criteria outside wordlines WL_OUT at a voltage level higher than the ground voltage VSS (e.g., pass voltage VPS) between the second time point t2 and the fourth time point t4. In this case, as shown by the dotted line, the channel potential of the inhibit memory transistor MT_IHB may be increased compared to the case where the row decoder 120 decreases the voltage level of the criteria outside wordlines WL_OUT to the ground voltage VSS after the second time point t2.

FIGS. 7 to 12 are diagrams showing channel potentials of program strings and inhibit strings between the first to fourth time points of FIG. 6. The horizontal axis of the graphs illustrated in FIGS. 7 to 13 may represent a location (e.g., a location on a silicon body SB), and the vertical axis may represent a channel potential voltage.

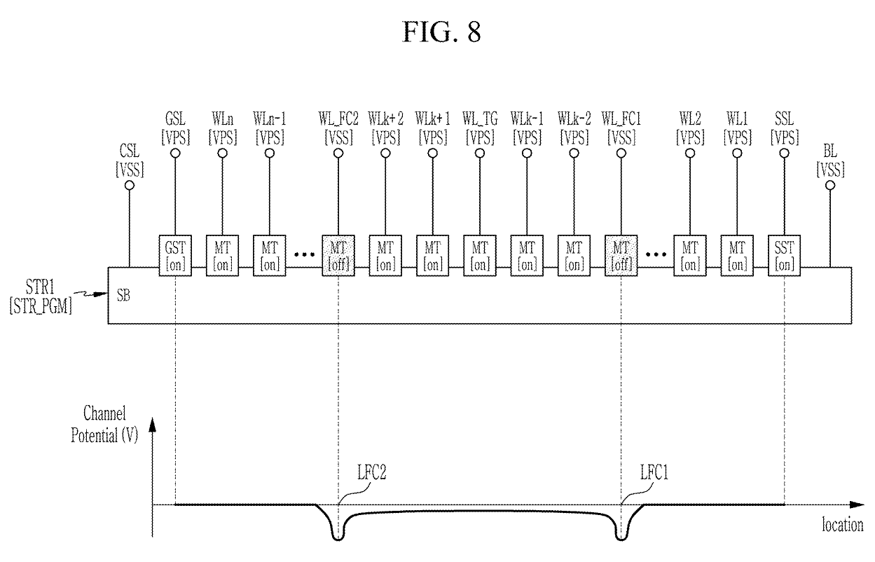

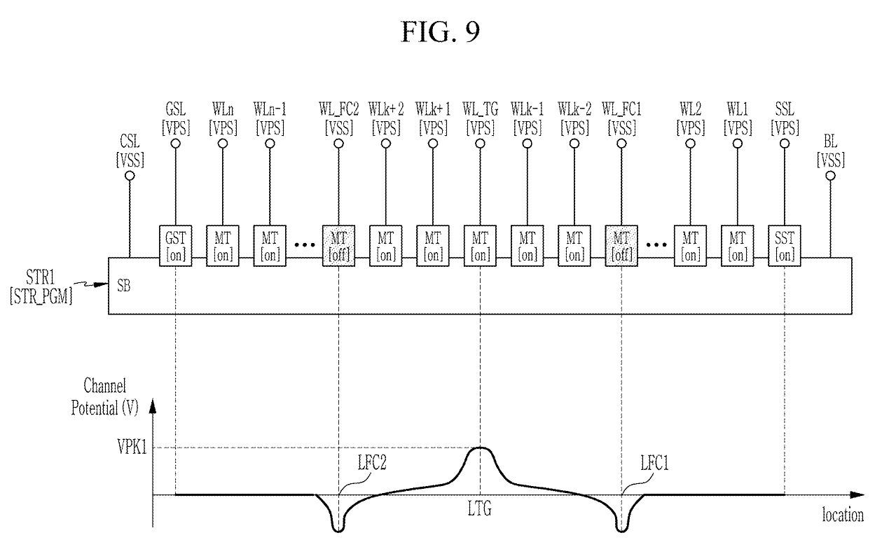

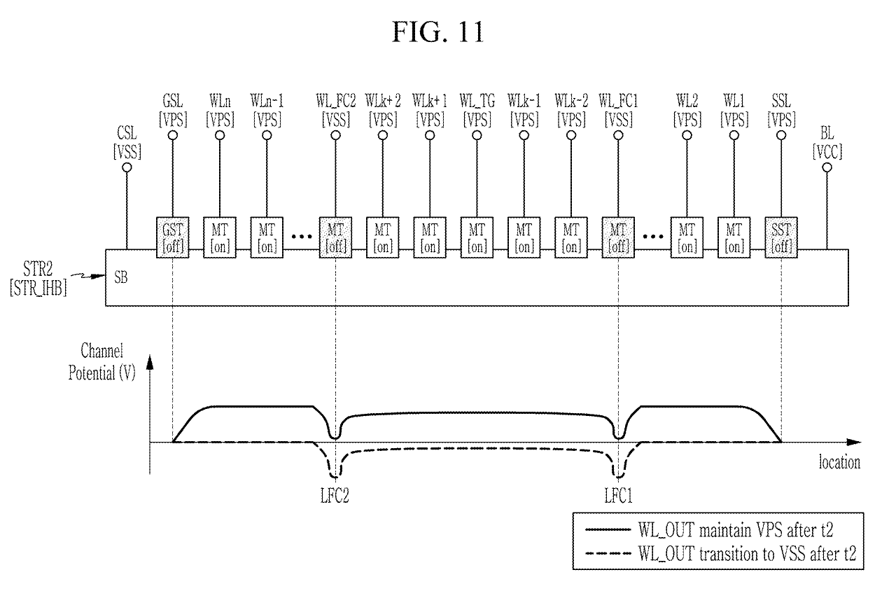

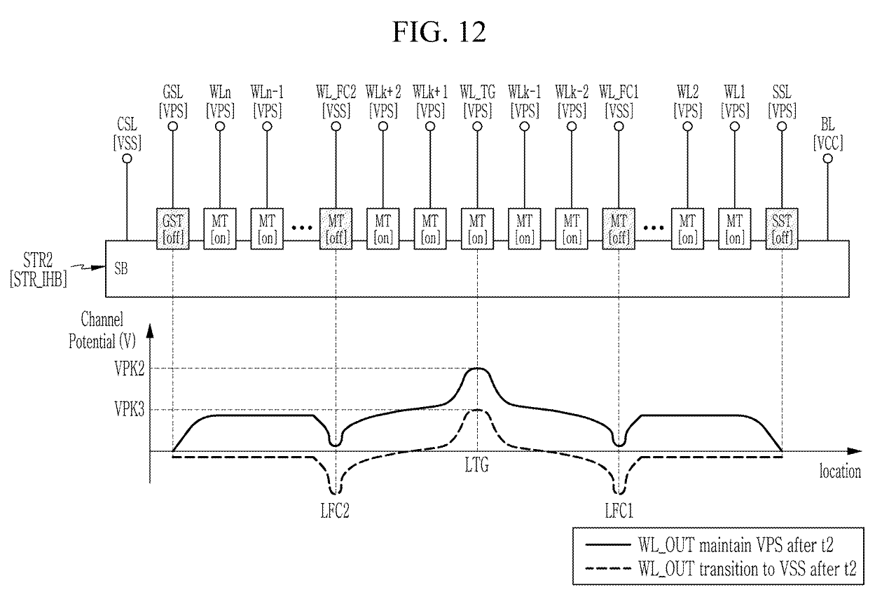

Hereinafter, with reference to FIG. 7, the channel potential of the program string STR_PGM between the first time point t1 and the second time point t2 is described; with reference to FIG. 8, the channel potential of the program string STR_PGM between the second time point t2 and the third time point t3 is described; with reference to FIG. 9, the channel potential of the program string STR_PGM between the third time point t3 and the fourth time point t4 is described; with reference to FIG. 10, the channel potential of the inhibit string STR_IHB between the first time point t1 and the second time point t2 is described; with reference to FIG. 11, the channel potential of the inhibit string STR_IHB between the second time point t2 and the third time point t3 is described; with reference to FIG. 12, the channel potential of the inhibit string STR_IHB between the third time point t3 and the fourth time point t4 is described.

For the sake of concise explanation, in the following, it is assumed that the channel potential of the program string STR_PGM and the inhibit string STR_IHB before the first time point t1 is '0 V', but the scope of the present disclosure is not limited thereto.

For a more concise explanation, hereinafter, it is assumed that two wordlines are located between the first focus criteria wordline WL_FC1 and the target wordline WL_TG, and that two wordlines are located between the second focus criteria wordline WL_FC2 and the target wordline WL_TG. For example, an example is described below in which both 'a' and 'b' are '3'. However, the scope of the present disclosure is not limited thereto.

For a more concise explanation, it is assumed below that the row decoder 120 collectively controls all criteria outside wordlines WL_OUT between the second time point t2 and the third time point t3. For example, hereinafter, an embodiment in which the row decoder 120 provides a pass voltage VPS to all of the criteria outside wordlines WL_OUT between the second time point t2 and the third time point t3 will be representatively described. However, the scope of the present disclosure is not limited thereto, and the row decoder 120 may also control the criteria outside wordlines WL_OUT independently.

Referring to FIGS. 1 to 7, between the first time point t1 and the second time point t2, the voltage level of the program bitline BL_PGM may be a ground voltage VSS, and the voltage levels of the string select line SSL and the ground select line GSL may be a pass voltage VPS. In this case, the string select transistor SST and ground select transistor GST included in the program string STR_PGM may be turned on. For example, the string select transistor SST and the ground select transistor GST may be turned on based on the voltage level of the program bitline BL_PGM.

The voltage level of the plurality of wordlines WL between the first time point t1 and the second time point t2 may be the pass voltage VPS. In this case, each of the plurality of memory transistors MT included in the program string STR_PGM may be turned on.

Accordingly, the channel potential of each of the plurality of memory transistors MT included in the program string STR_PGM may be determined based on the voltage level (e.g., ground voltage VSS) of the common source line CSL and the program bitline BL_PGM. For example, the channel potential of the silicon body SB corresponding to the program string STR_PGM between the first time point t1 and the second time point t2 may be '0V'.

Next, referring further to FIG. 8, at the second time point t2, the voltage level of the first and second focus criteria wordlines WL_FC1, WL_FC2 may be reduced to the ground voltage VSS. In this case, the memory transistors MT connected to the first and second focus criteria wordlines WL_FC1, WL_FC2 may be turned off.

As the voltage levels of the first and second focus criteria wordlines WL_FC1, WL_FC2 decrease to the ground voltage VSS, the channel potentials of the first and second focus criteria locations LFC1, LFC2 corresponding to the first and second focus criteria wordlines WL_FC1, WL_FC2, respectively, may decrease. For example, between the second time point t2 and the third time point t3, the channel potential of the first and second focus criteria locations LFC1, LFC2 may decrease based on a difference between the threshold voltage of the memory transistors MT connected to the first and second focus criteria wordlines WL_FC1, WL_FC2 and the ground voltage VSS.

In an embodiment, as the channel potential of the first and second focus criteria locations LFC1, LFC2 decreases, the channel potential between the first and second focus criteria locations LFC1, LFC2 may also decrease slightly.

Next, referring further to FIG. 9, at the third time point t3, the voltage level of the target wordline WL_TG may be increased to the program voltage VPGM. In this case, since the charge focus section CFS is floated, the channel potential of the charge focus section CFS may rise together with the voltage level of the target wordline WL_TG. For example, between the third time point t3 and the fourth time point t4, the channel potential of the target location LTG corresponding to the target wordline WL_TG may rise to the first peak voltage VPK1.

In an embodiment, the difference between the program voltage VPGM and the first peak voltage VPK1 may be great enough to change the electric polarization of the ferroelectric layer FL of the program memory transistor MT_PGM. For example, the difference between the program voltage VPGM and the first peak voltage VPK1 may be greater than the magnitude of the coercive voltage for the ferroelectric layer FL. In other words, the first peak voltage VPK1 may be a voltage low enough that the program memory transistor MT_PGM may be programmed.

In an embodiment, the phenomenon in which the channel potential of the memory transistor MT increases as the voltage of the wordline WL increases may occur due to coupling between the wordline WL and the channel CH. However, the scope of the present disclosure is not limited to the specific reason why the channel potential of the memory transistor MT increases as the voltage of the wordline WL increases.

Referring to FIGS. 1 to 6 and 10, the voltage level of the inhibit bitline BL_IHB at the first time point t1 may be the power supply voltage VCC. Therefore, the string select transistor SST and ground select transistor GST of the inhibit string STR_IHB may be turned off by the voltage level of the inhibit bitline BL_IHB.

At the first time point t1, the voltage level of the plurality of wordlines WL may be increased to the pass voltage VPS. In this case, since the string select transistor SST and the ground select transistor GST are turned off, the channel potential of the inhibit string STR may rise along with the voltage levels of the plurality of wordlines WL increases.

Next, referring further to FIG. 11, at the second time point t2, the voltage level of the first and second focus criteria wordlines WL_FC1, WL_FC2 may be decreased to the ground voltage VSS. In this case, the memory transistors MT connected to the first and second focus criteria wordlines WL_FC1, WL_FC2 may be turned off. In this case, similarly to what was described above with reference to FIG. 8, the channel potentials of the first and second focus criteria locations LFC1, LFC2 may decrease.

Referring to the graph illustrated in dotted lines of FIG. 11, when the voltage level of the plurality of criteria outside wordlines WL_OUT decreases to the ground voltage VSS after the second time point t2 as illustrated in dotted lines of FIG. 6, the channel potential of the charge non-focus section CNFS may decrease. In this case, as the channel potential of the charge non-focus section CNFS decreases, the channel potential of the charge focus section CFS may decrease together. That is, the graph illustrated in the dotted line may represent the channel potential of the inhibit string STR_IHB when both the voltage level drops of the plurality of criteria outside wordlines WL_OUT and the voltage level drops of the first and second focus criteria wordlines WL_FC1, WL_FC2 occur.

On the other hand, referring to the graph illustrated in solid lines in FIG. 11, if the voltage levels of the plurality of criteria outside wordlines WL_OUT are maintained at the pass voltage VPS after the second time point t2, as illustrated in solid lines in FIG. 6, the channel potential of the charge non-focus section CNFS may be maintained at a similar level as before the second time point t2. For example, the channel potential of the charge non-focus section CNFS may be reduced only by the voltage level drop of the first and second focus criteria wordlines WL_FC1, WL_FC2; and in this case, the channel potential of the charge non-focus section CNFS between the second time point t2 and the third time point t3 may be have a similar level as before the second time point t2. That is, the graph illustrated by the solid line may represent the channel potential of the inhibit string STR_IHB when only the voltage level drop of the first and second focus criteria wordlines WL_FC1, WL_FC2 occurs.

Comparing the graphs drawn with solid lines and the graphs drawn with dotted lines, the channel potential of the charge focus section CFS may be higher when the voltage level of the plurality of criteria outside wordlines WL_OUT is maintained at the pass voltage VPS after the second time point t2 than when the voltage level of the plurality of criteria outside wordlines WL_OUT is reduced to the ground voltage VSS after the second time point t2.

Comparing the graph illustrated in the dotted line with the channel potential level of the program string STR_PGM described above with reference to FIG. 8, the channel potential at the location corresponding to the inhibit memory transistor MT_IHB between the second time point t2 and the third time point t3 may have a level almost similar to the channel potential at the location corresponding to the program memory transistor MT_PGM. In this case, since the channel potentials of the program memory transistor MT_PGM and the inhibit memory transistor MT_IHB are almost similar, there is a very high possibility that either (or, both) the program operation for the program memory transistor MT_PGM or the program inhibit operation for the inhibit memory transistor MT_IHB fail.

On the other hand, when comparing the graph illustrated in the solid line with the channel potential level of the program string STR_PGM described above with reference to FIG. 8, the channel potential at the location corresponding to the inhibit memory transistor MT_IHB between the second time point t2 and the third time point t3 may be higher than the channel potential at the location corresponding to the program memory transistor MT_PGM. In this case, both the program operation for the program memory transistor MT_PGM and the program inhibit operation for the inhibit memory transistor MT_IHB may succeed.

More specifically, referring further to FIG. 12, at the third time point t3, the voltage level of the target wordline WL_TG may be increased to the program voltage VPGM. In this case, similarly to what was described above with reference to FIG. 9, the channel potential of the target location LTG corresponding to the target wordline WL_TG may increase.

For example, referring to the graph illustrated in the solid line, when the voltage level of the target wordline WL_TG rises to the program voltage VPGM while the voltage level of the plurality of criteria outside wordlines WL_OUT is maintained with the pass voltage VPS, the channel potential of the target location LTG may rise to the second peak voltage VPK2. On the other hand, referring to the graph shown in the dotted line, when the voltage level of the target wordline WL_TG rises to the program voltage VPGM while the voltage level of the plurality of criteria outside wordlines WL_OUT is dropped to the ground voltage VSS, the channel potential of the target location LTG may rise to the third peak voltage VPK3.

The second peak voltage VPK2 may be a higher voltage than the third peak voltage VPK3. For example, a difference between the second peak voltage VPK2 and the program voltage VPGM may be greater than a difference between the third peak voltage VPK3 and the program voltage VPGM.

In an embodiment, the third peak voltage VPK3 may have a similar voltage level as the first peak voltage VPK1. That is, when the ground voltage VSS is provided to the plurality of criteria outside wordlines WL_OUT while the program voltage VPGM is provided to the target wordline WL_TG, both the program memory transistor MT_PGM and the inhibit memory transistor MT_IHB may be programmed, or both the program memory transistor MT_PGM and the inhibit memory transistor MT_IHB may not be programmed.

In an embodiment, the second peak voltage VPK2 may have a voltage level sufficiently higher than the first peak voltage VPK1. In this case, the difference between the second peak voltage VPK2 and the program voltage VPGM may not be large enough to change the threshold voltage of the inhibit memory transistor MT_IHB. In other words, the difference between the second peak voltage VPK2 and the program voltage VPGM may be smaller than the coercive voltage for the ferroelectric layer FL. On the other hand, the difference between the first peak voltage VPK1 and the program voltage VPGM may be large enough to change the threshold voltage of the program memory transistor MT_PGM. That is, when a pass voltage VPS (or a voltage higher than the ground voltage VSS) is provided to a plurality of criteria outside wordlines WL_OUT (or some of them) while a program voltage VPGM is provided to a target wordline WL_TG, the program memory transistor MT_PGM may be successfully programmed and, at the same time, the inhibit memory transistor MT_IHB may be successfully program-inhibited.

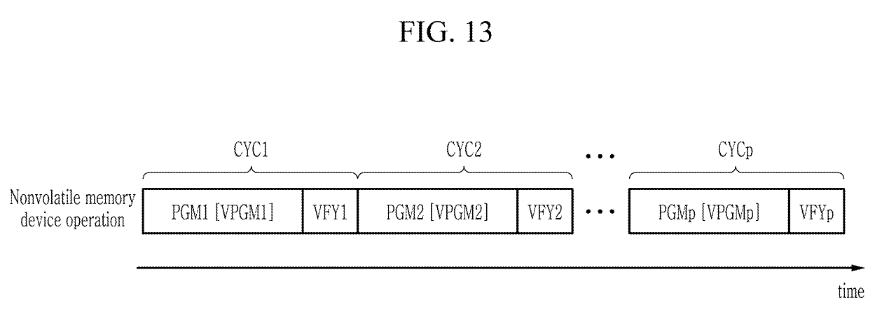

FIG. 13 is a diagram showing the operation of the nonvolatile storage device of FIG. 1 according to an embodiment of the present disclosure. Referring to FIGS. 1 to 13, the nonvolatile memory device 100 may perform a program operation on a program memory transistor MT_PGM using an incremental operation pulse programming (ISPP) scheme. That is, the nonvolatile memory device 100 may change the threshold voltage of the program memory transistor MT_PGM to an intended level by performing the plurality of program cycles CYC with gradually increasing the voltage level of the program voltage VPGM. For example, the nonvolatile memory device 100 may decrease the threshold voltage of the program memory transistor MT_PGM to an intended level by sequentially perform first to p-th program cycles CYC1 to CYCp.

Each of the plurality of program cycles CYC may include a program operation PGM and a verify operation VFY. For example, the first to p-th program cycles CYC1 to CYCp may include the first to p-th program operations PGM1 to PGMp and the first to p-th verification operations VFY1 to VFYp, respectively. In this case, each of the first to p-th program operations PGM1 to PGMp may be performed in the manner described above with reference to FIGS. 1 to 12. Each of the first to p-th verification operations VFY1 to VFYp may refer to an operation of testing a threshold voltage of a program memory transistor MT_PGM by providing a verification voltage to the target wordline WL_TG.

The nonvolatile memory device 100 may perform first to p-th program operations PGM1 to PGMp based on first to p-th program voltages VPGM1 to VPGMp, respectively. The first to p-th program voltages VPGM1 to VPGMp may form an increasing sequence. For example, the second program voltage VPGM2 may be higher than the first program voltage VPGM1, and the third program voltage VPGM3 may be higher than the second program voltage VPGM2.

In an embodiment, the intervals between the first to p-th program voltages VPGM1 to VPGMp may be equal each other. For example, the first to p-th program voltages VPGM1 to VPGMp may form an arithmetic sequence.

The threshold voltage of the program memory transistor MT_PGM may gradually decrease according to the voltage level of the program voltage VPGM. For example, each time a program cycle CYC is performed, the threshold voltage of the program memory transistor MT_PGM may decrease slightly.

In an embodiment, the length of time over which the first to p-th program operations PGM1 to PGMp are performed may be equal to each other. However, the scope of the present disclosure is not limited thereto. For example, the time interval between the third time point t3 and the fourth time point t4 described above with reference to FIG. 6 may be the same or different for cases where the first to p-th program operations PGM1 to PGMp are performed.

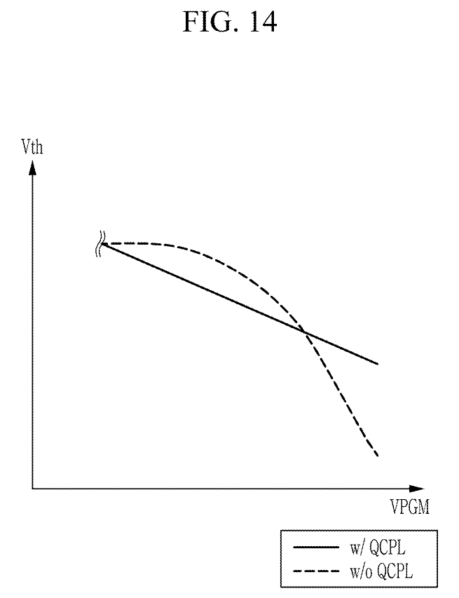

FIG. 14 is a diagram showing the relationship between the program voltage and the threshold voltage of the program memory transistor according to the embodiment of FIG. 13. Referring to FIGS. 1 to 14, as the plurality of program cycles CYC are sequentially performed, the voltage level of the program voltage VPGM used in the program operation PGM may gradually increase.

Referring to the graph illustrated in dotted lines, if the row decoder 120 operates not based on the charge control program logic QCPL described with reference to FIGS. 1 to 13 above, the relationship between the program voltage VPGM and the threshold voltage of the program memory transistor MT_PGM may be nonlinear. For example, even if the intervals between the first to p-th program voltages VPGM1 to VPGMp are the same, the intervals between the threshold voltages of the program memory transistors MT_PGM after each of the first to p-th program operations PGM1 to PGMp is completed may not be same. That is, even though gradually increasing the program voltage VPGM as each program cycle CYC is completed, the threshold voltage of the program memory transistor MT_PGM may decrease nonlinearly. In this case, it may be difficult to control the threshold voltage of the program memory transistor MT_PGM to have the intended voltage level by controlling the program voltage VPGM.

On the other hand, referring to the graph illustrated in solid lines, when the row decoder 120 operates based on the charge control program logic QCPL described with reference to FIGS. 1 to 13 above, the relationship between the program voltage VPGM and the threshold voltage of the program memory transistor MT_PGM may be linear. For example, when the intervals of the first to p-th program voltages VPGM1 to VPGMp are the same, the intervals of the threshold voltages of the program memory transistors MT_PGM after each of the first to p-th program operations PGM1 to PGMp is completed may be same. Accordingly, the nonvolatile memory device 100 may linearly reduce the threshold voltage of the program memory transistor MT_PGM by gradually increasing the program voltage VPGM each time each program cycle CYC is completed. In this case, it may be easier to control the program voltage VPGM to make the threshold voltage of the program memory transistor MT_PGM at the intended voltage level.

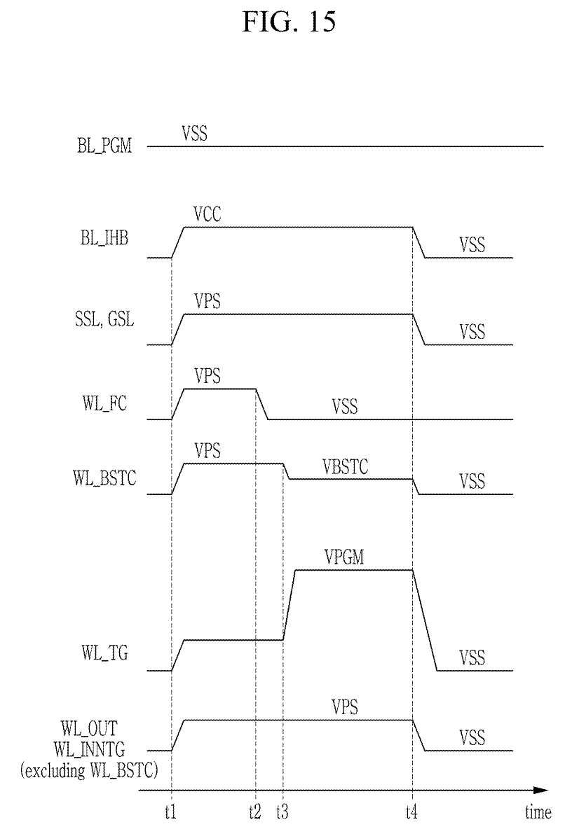

In an embodiment, the relationship between the program voltage VPGM and the threshold voltage of the program memory transistor MT_PGM may be determined by various factors. For example, the slope of the graph shown as a solid line may be determined by various factors, such as the interval between the target wordline WL_TG and the first focus criteria wordline WL_FC1 (e.g., 'a'), the interval between the target wordline WL_TG and the second focus criteria wordline WL_FC2 (e.g., 'b'), the time interval between the third time point t3 and the fourth time point t4, etc. However, the scope of the present disclosure is not limited thereto, and the relationship between the program voltage VPGM and the threshold voltage of the program memory transistor MT_PGM may vary depending on the operation method of the row decoder 120 according to the charge control program logic QCPL, as described below with reference to FIGS. 15 to 19.

FIG. 15 is a timing diagram showing in more detail the operation of a nonvolatile memory device according to the charge control program logic of FIG. 2 according to an embodiment. The horizontal axis of FIG. 15 may represent time, and the vertical axis may represent voltage level. Hereinafter, the differences from the operation of the row decoder 120 described above with reference to FIG. 6 will be mainly explained. For example, the operation of the nonvolatile memory device 100 between the first time point t1 and the third time point t3 is similar to that described above with reference to FIG. 6, and therefore, a detailed description is omitted.

The row decoder 120 may determine some of the plurality of criteria internal non-target wordlines WL_INNTG as boost control wordlines WL_BSTC. For example, the row decoder 120 may determine one or more of the wordlines located between the target wordline WL_TG and the first focus criteria wordline WL_FC1 and wordlines located between the target wordline WL_TG and the first focus criteria wordline WL_FC2, as the boost control wordline WL_BSTC.

Hereinafter, for a more concise explanation, it is assumed that the row decoder 120 determines one of the wordlines located between the target wordline WL_TG and the first focus criteria wordline WL_FC1, and one of the wordlines located between the target wordline WL_TG and the first focus criteria wordline WL_FC2 as the boost control wordline WL_BSTC.

In an embodiment, the interval of each of the boost control wordlines WL_BSTC relative to the target wordline WL_TG may be equal to each other. For example, the row decoder 120 may determine the (k-2)-th wordline WLk-2 and the (k+2)-th wordline WL_k+2 as boost control wordlines WL_BSTC. However, the scope of the present disclosure is not limited thereto.

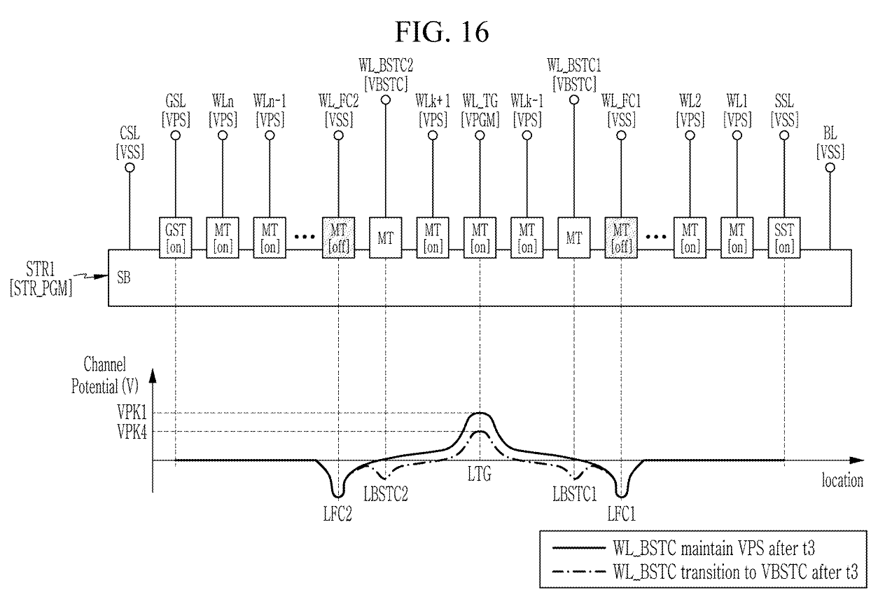

At the third time point t3, the row decoder 120 may decrease the voltage level of one or more boost control wordlines WL_BSTC. For example, the row decoder 120 may decrease the voltage level of one or more boost control wordlines WL_BSTC to a boost control voltage VBSTC. In this case, as the voltage level of the boost control wordline WL_BSTC decreases, the channel potential corresponding to the program memory transistor MT_PGM may decrease as well. The specific manner in which the channel potential corresponding to the program memory transistor MT_PGM decreases as the voltage level of the boost control wordline WL_BSTC decreases is described in more detail with reference to FIG. 16 below.

In an embodiment, the boost control voltage VBSTC may be a lower voltage than the pass voltage VPS. For example, the boost control voltage VBSTC may be a voltage lower than the pass voltage VPS by half of the difference between the program voltage VPGM and the pass voltage VPS. However, the scope of the present disclosure is not limited thereto.

Also, for a more concise explanation, FIG. 15 illustrates that the boost control voltage VBSTC is higher than the ground voltage VSS, but the scope of the present disclosure is not limited thereto. For example, the boost control voltage VBSTC may be a voltage lower than the ground voltage VSS.

FIG. 16 is a diagram showing the channel potential of a program string between a third time point and a fourth time point according to the embodiment of FIG. 15. Hereinafter, with reference to FIGS. 1 to 16, the channel potential of the program string STR_PGM when the row decoder 120 provides the program voltage VPGM to the target wordline WL_TG while providing the boost control voltage VBSTC to the boost control wordline WL_BSTC will be described.

The horizontal axis of the graphs illustrated in FIG. 16 may represent a location (e.g., a location on a silicon body SB), and the vertical axis may represent a channel potential voltage.

The graph drawn with a solid line represents the channel potential of the program string STR_PGM described with reference to FIGS. 6 and 10 above. That is, the graph drawn with a solid line represents the channel potential of the program string STR_PGM when the voltage level of one or more boost control wordlines WL_BSTC is maintained at the pass voltage VPS after the third time point t3. The graph depicted in solid lines has been previously explained with reference to FIGS. 6 to 10, so a detailed description is omitted.

The graph drawn with a one-dotted-one-dashed line represents the channel potential of the program string STR_PGM described above with reference to FIG. 15. That is, the graph depicted by the one-dotted-one-dashed line represents the channel potential of the program string STR_PGM when the voltage level of one or more boost control wordlines WL_BSTC is reduced to the boost control voltage VBSTC after the third time point t3.

Referring to the graph illustrated in a one-dotted-one-dashed line, at the third time point t3, the row decoder 120 may decrease the voltage level of one or more boost control wordlines WL_BSTC to the boost control voltage VBSTC based on the charge control program logic QCPL. In this case, since the channel of the charge focus section CFS is floated, the channel potential of the boost control location LBSTC corresponding to the boost control wordline WL_BSTC may decrease. For example, when the row decoder 120 decreases the voltage level of the first and second boost control wordlines WL_BSTC1, WL_BSTC2 to the boost control voltage VBSTC, the channel potential of the first and second boost control locations LBSTC1, LBSTC2 corresponding to the first and second boost control wordlines WL_BSTC1, WL_BSTC2 may be decreased.

When the channel potential of the boost control locations LBSTC decreases, the overall channel potential of the charge focus section CFS may also be decreased. For example, when the channel potentials of the first and second boost control locations LBSTC1, LBSTC2 decrease, the channel potential of the target location LTG may decrease together. Accordingly, according to the embodiment of FIG. 15, even if the voltage level of the target wordline WL_TG rises to the program voltage VPGM, the channel potential of the target location LTG of the program string STR_PGM may rise only to the fourth peak voltage VPK4 that is lower than the first peak voltage VPK1. In this case, the difference between the channel potential of the program memory transistor MT_PGM and the program voltage VPGM may increase, and the possibility that the program for the program memory transistor MT_PGM be performed normally may increase.

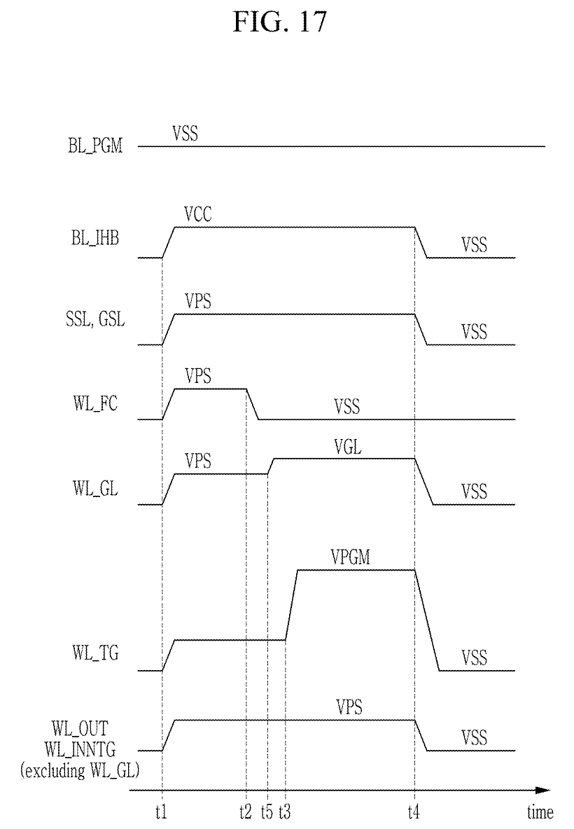

FIG. 17 is a timing diagram showing in more detail the operation of a nonvolatile memory device according to the charge control program logic of FIG. 2 according to an embodiment. The horizontal axis of FIG. 17 may represent time, and the vertical axis may represent voltage level. Hereinafter, the differences from the operation of the row decoder 120 described above with reference to FIG. 6 will be mainly explained. For example, the operation of the nonvolatile memory device 100 between the first time point t1 and the second time point t2 is similar to that described above with reference to FIG. 6, and therefore, a detailed description is omitted.

Referring to FIGS. 1 to 14 and FIG. 17, the row decoder 120 may determine some of the plurality of criteria internal non-target wordlines WL_INNTG as gap lessen wordlines WL_GL. For example, the row decoder 120 may determine one or more of the wordlines located between the target wordline WL_TG and the first focus criteria wordline WL_FC1, and the wordlines located between the target wordline WL_TG and the first focus criteria wordline WL_FC2 as the gap lessen wordlines WL_GL.

In the following, for a more concise explanation, it is assumed that the row decoder 120 determines two wordlines adjacent to the target wordline WL_TG as gap lessen wordlines WL_GL. For example, the row decoder 120 may determine the (k+1)-th wordline WLk+1 and the (k-1)-th wordline WL_k-1 as gap lessen wordlines WL_GL.

At the fifth time point t5 between the second time point t2 and the third time point t3, the row decoder 120 may increase the voltage level of the gap lessen wordlines WL_GL. For example, the row decoder 120 may increase the voltage level of the gap lessen wordlines WL_GL to a gap lessen voltage VGL. Thereafter, at the third time point t3, the row decoder 120 may increase the voltage level of the target wordline WL_TG to the program voltage VPGM.

In an embodiment, unlike that illustrated in FIG. 17, the row decoder 120 may float the gap lessen wordline WL_GL at the fifth time point t5. In this case, as the voltage of the target wordline WL_TG increases to the program voltage VPGM, the voltage level of the gap lessen wordline WL_GL may also be increased. In this case, the voltage level difference between the target wordline WL_TG and the gap lessen wordline WL_GL may be minimized also. That is, the scope of the present disclosure is not limited to a specific manner in which the row decoder 120 increases the voltage level of the gap lessen wordline WL_GL between the third time point t3 and the fourth time point t4.

In an embodiment, the gap lessen voltage VGL may be higher than the pass voltage VPS, but not too high to change the threshold voltage of the memory transistor MT. However, the scope of the present disclosure is not limited thereto.

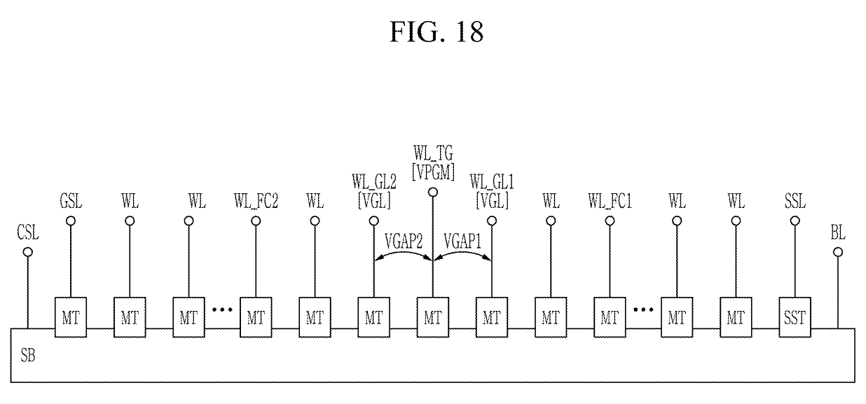

FIG. 18 is a diagram showing the voltage difference between a target wordline and adjacent wordlines according to the embodiment of FIG. 17. Referring to FIGS. 1 to 14 and FIGS. 17 to 18, the row decoder 120 may determine wordlines adjacent to the target wordline WL_TG as first gap lessen wordlines WL_GL1 and second gap lessen wordlines WL_GL2, respectively.

The row decoder 120 may increase the voltage levels of the first gap lessen wordline WL_GL1 and the second gap lessen wordline WL_GL2 to the gap lessen voltage VGL while providing the program voltage VPGM to the target wordline WL_TG. In this case, the voltage gap VGAP between the target wordline WL_TG and the gap lessen wordline WL_GL may be minimized. For example, according to the embodiment of FIG. 17, a first voltage gap VGAP1 between a first gap lessen wordline WL_GL1 and a target wordline WL_TG, and a second voltage gap VGAP2 between a second gap lessen wordline WL_GL2 and a target wordline WL_TG may be minimized. Therefore, according to an embodiment of the present disclosure, the probability of occurrence of wordline to wordline breakdown between a target wordline WL_TG and adjacent wordlines WLs (e.g., gap lessen wordlines WL_GL) may be minimized.

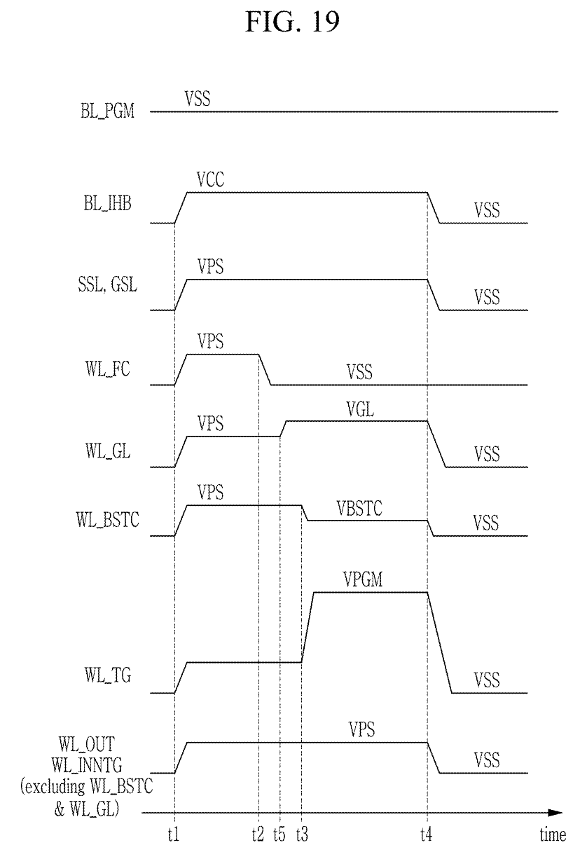

FIG. 19 is a timing diagram showing in more detail the operation of a nonvolatile memory device according to the charge control program logic of FIG. 2 according to an embodiment. The horizontal axis of FIG. 19 may represent time, and the vertical axis may represent voltage level. Hereinafter, the differences from the operation of the row decoder 120 described above with reference to FIG. 6 will be mainly explained. For example, the operation of the nonvolatile memory device 100 between the first time point t1 and the third time point t3 is similar to that described above with reference to FIG. 6, and therefore, a detailed description is omitted.

Similar to what was described above with reference to FIG. 15, the row decoder 120 may determine some of the plurality of criteria internal non-target wordlines WL_INNTG as boost control wordlines WL_BSTC. For example, the row decoder 120 may determine the (k-2)th wordline WLk-2 and the (k+2)th wordline WL_k+2 as boost control wordlines WL_BSTC. However, the scope of the present disclosure is not limited thereto.

Similar to what was described above with reference to FIG. 17, the row decoder 120 may determine some of the plurality of criteria internal non-target wordlines WL_INNTG as gap lessen wordlines WL_GL. For example, the row decoder 120 may determine the (k+1)-th wordline WLk+1 and the (k-1)-th wordline WL_k-1 as gap lessen wordlines WL_GL.

At the fifth time point t5, the row decoder 120 may increase the voltage level of the gap lessen wordlines WL_GL. At the third time point t3, the voltage level of the boost control wordlines WL_BSTC may be reduced. That is, the row decoder 120 may apply both the boost control scheme described above with reference to FIGS. 15 and 16, and the gap lessen scheme described above with reference to FIGS. 17 and 18. In this case, the channel potential of the program memory transistor MT_PGM is reduced, which may increase the possibility that the program memory transistor MT_PGM is successfully programmed, and the voltage gap VGAP is reduced, which may decrease the possibility that insulation breakdown occurs between wordlines.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A nonvolatile memory device, comprising:
a string including a ground select transistor, a string select transistor, and a plurality of memory transistors; and
a row decoder configured to control a ground select line connected to the ground select transistor, a string select line connected to the string select transistor, and a plurality of wordlines respectively connected to the plurality of memory transistors,
wherein during a first time period in which the row decoder provides a program voltage to a target wordline, which is one of the plurality of wordlines, the row decoder is configured to:
provide a first voltage to a first wordline, among the plurality of wordlines, located between the target wordline and the string select line, and to a second wordline, among the plurality of wordlines, located between the target wordline and the ground select line; and
provide a second voltage higher than the first voltage to at least one of:
a first plurality of wordlines, among the plurality of wordlines, located between the first wordline and the string select line; and
a second plurality of wordlines, among the plurality of wordlines, located between the second wordline and the ground select line.

2. The nonvolatile memory device of claim 1, wherein:
a first interval between the target wordline and the first wordline corresponds to a second interval between the target wordline and the second wordline.

3. The nonvolatile memory device of claim 1, wherein each of the plurality of memory transistors includes a ferroelectric layer.

4. The nonvolatile memory device of claim 1, wherein:
the row decoder is configured to provide, to the first wordline and the second wordline during a second time period preceding the first time period, a third voltage higher than the first voltage and lower than the program voltage, and
the second voltage is equal to or lower than the third voltage.

5. The nonvolatile memory device of claim 4, wherein during the second time period, the row decoder is configured to:
provide the third voltage to one or more first internal non-target wordlines, among the plurality of wordlines, located between the first wordline and the target wordline, and to one or more second internal non-target wordlines, among the plurality of wordlines, located between the second wordline and the target wordline.

6. The nonvolatile memory device of claim 5, wherein during the second time period, the row decoder is configured to:
provide the third voltage to the first plurality of wordlines and the second plurality of wordlines.

7. The nonvolatile memory device of claim 5, wherein during the first time period, the row decoder is configured to:
provide a boost control voltage lower than the third voltage to a first boost control wordline, which is one of the one or more first internal non-target wordlines, and to a second boost control wordline, which is one of the one or more second internal non-target wordlines.

8. The nonvolatile memory device of claim 5, wherein during the first time period, the row decoder is configured to:
increase a voltage level of a third wordline which is one of the one or more first internal non-target wordlines and a fourth wordline which is one of the one or more second internal non-target wordlines, to higher than the third voltage.

9. The nonvolatile memory device of claim 8, wherein during the first time period, the row decoder is configured to:
provide a voltage higher than the third voltage to the third wordline and the fourth wordline.

10. The nonvolatile memory device of claim 8, wherein during the first time period, the row decoder is configured to:
float the third wordline and the fourth wordline.

11. The nonvolatile memory device of claim 8, wherein:
the third wordline and fourth wordline are adjacent to the target wordline.

12. The nonvolatile memory device of claim 1, wherein:
a threshold voltage of a program memory transistor after the first time period is lower than a threshold voltage of the program memory transistor before the first time period, and
the program memory transistor is one of the plurality of memory transistors and connected to the target wordline.

13. An operation method of a nonvolatile memory device including a program string and an inhibit string sharing a string select line, a ground select line, and a plurality of wordlines, the operation method comprising:
setting a voltage level of the plurality of wordlines to a first voltage;
decreasing a voltage level of first and second wordlines among the plurality of wordlines to a second voltage; and
increasing a voltage level of a target wordline, which is one of the plurality of wordlines and is located between the first and second wordlines, to a third voltage,
wherein during performing the decreasing and increasing, among the plurality of wordlines, voltage levels of a first plurality of wordlines located between the first wordline and the string select line, and voltage levels of a second plurality of wordlines located between the second wordline and the ground select line, are maintained with the first voltage.

14. The operation method of claim 13, wherein:
the first voltage is a pass voltage, the second voltage is a ground voltage lower than the first voltage, and the third voltage is a program voltage higher than the first voltage.

15. The operation method of claim 13, further comprising:
decreasing, among the plurality of wordlines, a voltage level of a first boost control wordline located between the first wordline and the target wordline, and a voltage level of a second boost control wordline located between the second wordline and the target wordline, from the first voltage to a fourth voltage.

16. The operation method of claim 13, before the increasing, further comprising:
increasing, among the plurality of wordlines, a voltage level of a wordline located between the first wordline and the target wordline, and a voltage level of a wordline located between the second wordline and the target wordline, from the second voltage to a fifth voltage.

17. The operation method of claim 13, further comprising:
setting a voltage level of a first bitline connected to the program string to a ground voltage; and
setting a voltage level of a second bitline connected to the inhibit string to a power supply voltage.

18. A nonvolatile memory device, comprising:
a program string including first and second memory transistors, and a program memory transistor connected between the first and second memory transistors;
an inhibit string including third and fourth memory transistors, and an inhibit memory transistor connected between the third and fourth memory transistors; and
a row decoder configured to control a first wordline connected to the first and third memory transistors, a second wordline connected to the second and fourth memory transistors, and a target wordline connected to the program memory transistor and the inhibit memory transistor,
wherein during a first time period in which the row decoder provides a program voltage to the target wordline:
the row decoder is configured to provide a ground voltage to the first wordline and the second wordline, and a first channel potential level corresponding to the program memory transistor is lower than a second channel potential level corresponding to the inhibit memory transistor.

19. The nonvolatile memory device of claim 18, wherein:
the program string further includes a first string select transistor, a first ground select transistor, a first plurality of memory transistors connected between the first string select transistor and the first memory transistor, and a second plurality of memory transistors connected between the first ground select transistor and the second memory transistor,
the inhibit string further includes a second string select transistor, a second ground select transistor, a third plurality of external memory transistors connected between the second string select transistor and the third memory transistor, and a fourth plurality of memory transistors connected between the second ground select transistor and the fourth memory transistor,
the row decoder is further configured to control a string select line connected to the first and second string select transistors, a ground select line connected to the first and second ground select transistors, a first plurality of wordlines connected to the first and third plurality of memory transistors, and a second plurality of wordlines connected to the second and fourth plurality of memory transistors,
the row decoder is further configured to maintain voltage levels of the first plurality of wordlines and the second plurality of wordlines higher than the ground voltage during the first time period.

20. The nonvolatile memory device of claim 18, wherein:
each of the first to fourth focus transistors, the program memory transistor, and the inhibit memory transistor includes a ferroelectric layer.
